(19) United States
(12) Patent Application Publication
(10) Pub. No.: US 2020/0249279 A1
(43) Pub. Date: Aug. 6, 2020

(54) METHOD AND DIAGNOSTIC SERVICE TOOL FOR A BATTERY PACK

(71) Applicant: GM Global Technology Operations LLC, Detroit, MI (US)

(72) Inventors: Andrew J. Cornelli, Clawson, MI (US); Ciro A. Spigno, Waterford, MI (US)

(73) Assignee: GM Global Technology Operations LLC, Detroit, MI (US)

(21) Appl. No.: 16/268,965

(22) Filed: Feb. 6, 2019

(51) Int. Cl. G01R 31/3842; G01R 31/367; G01R 31/36; G01R 31/396; B60L 58/13; H01M 2/10; H01M 10/48; H01M 10/42

(52) U.S. Cl. CPC G01R 31/3842; G01R 31/367; G01R 31/3646; G01R 31/396; H01M 2010/4278; H01M 2/1077; H01M 10/482; H01M 10/425; H01M 2010/4271; B60L 58/13

(57) ABSTRACT

A method for diagnosing battery pack faults includes connecting a diagnostic service tool (DST) to the battery pack and measuring battery parameters using one or more electrical sensors, including a voltage of each cell/cell group. The method includes calculating, via the DST using the battery parameters, a section-average state of charge (SOC) of each battery section and identifying, from among the cells/cell groups of each respective section, a particular one of the cells or cell groups having a lowest cell SOC. For each respective battery section, a ΔSOC value is calculated as a difference between the section-average and lowest cell SOC, including comparing the ΔSOC value for each section to a calibrated threshold. A repair action is executed or initiated with respect to the battery pack, via the DST, responsive to the ΔSOC value for one or more sections exceeding the calibrated threshold.

### INTRODUCTION

Electrochemical battery packs are used as direct-current (DC) power supplies aboard vehicles and mobile systems, in power plants, and as core components of other electrical systems. High-energy battery packs are constructed from multiple sections of interconnected battery cells. Each battery cell has an internal cell stack-up, which in some configurations includes a thin layer of insulating material positioned between oppositely-charged electrode foils. The cell stack-up is sealed within an outer foil pouch containing an electrolyte material, with extensions of the electrode foils protruding from the pouch edges to thereby form positive and negative cell tabs. The cell tabs are ultimately welded or joined together via conductive interconnecting members, bus bars, or weld caps to construct a given battery section.

Individual cell voltages and states of charge of the cells are calculated, tracked, and accounted for using a battery system manager, e.g., an onboard battery controller that monitors the health of the battery pack, estimates remaining capacity or electric range, and informs automatic cell-balancing algorithms regarding a charge imbalance that may be present within the battery pack. However, latent construction defects, electrical faults, or errors in the execution of such cell-balancing algorithms or associated cell sense hardware, and/or variations in self-balancing rates of the various battery cells, can result in cell voltage differences or charge imbalances throughout the battery pack.

Electrical faults resulting from the above-noted conditions may prompt a user of a vehicle or other electrical system equipped with a battery pack to visit a service facility for repair or replacement of the battery pack. Given the complexity of emerging high-energy, multi-cell battery packs, a system service technician may be required to extract voltage data from the battery pack as a binary file and relay the extracted binary file to an offsite battery analysis facility. There, a team of battery specialists may convert and analyze the binary data to determine if and where a defective battery cell may be present within the serviced battery pack. A repair action derived by the battery specialists is thereafter transmitted to the on-site service technician for repair or replacement of the battery pack. The overall diagnostic and repair cycle may be suboptimal in terms of time, cost, and potential diagnostic inaccuracy.

### SUMMARY

The present disclosure pertains to methods and service tools for diagnosing a multi-cell battery pack, e.g., a high-voltage battery pack for powering a battery electric or hybrid electric vehicle. The battery pack contemplated herein includes multiple series-connected battery cells or groups thereof. Each respective cell or cell group is constructed from parallel-connected battery cells of the foil pouch construction generally described above, or of a similar construction. Representative faults in such a battery pack commonly include low-cell voltage levels and battery cell-sensing faults, both of which may be diagnosed and treated using the strategy and service tool disclosed herein.

The service tool may be embodied as a portable computer device that is configured to interface with an onboard controller, e.g., a battery management system (BMS) of an example motor vehicle, via a serial port interface (SPI) connection or other suitable protocol. As will be appreciated, a BMS may be used to monitor the state of charge and health of a battery pack, and to regulate operation and thermal levels of the battery pack, and therefore is continuously populated with battery voltage and current data that may be used to advantage as part of the present method.

Once connected to the BMS and/or to the battery pack, the service tool is configured to improve battery pack diagnostic accuracy via calculation of cell-level and battery section-level differential state of charge (SOC) values, i.e., a difference or “delta” (Δ) between an average SOC of each battery section and an SOC of the weakest/lowest energy battery cell/cell group thereof. The cell and section ΔSOC values are thereafter used to diagnose specific battery faults, including the above-noted low-cell fault and some types of extreme cell-sensing faults. For instance, many cell-sensing faults are due to resistor issues that present themselves as a high cell adjacent to a low cell. If the SOC of the low cell is still reasonably close to the SOC of the high cell, the ΔSOC value may not be able to detect the cell-sensing fault. In such a case, cell voltages of adjacent cells could be compared. An appropriate repair action is then taken responsive to the diagnosed faults.

In an example embodiment, a method is disclosed for diagnosing faults in a battery pack having a plurality of series-connected battery cells or cell groups. The battery cells or cell groups are arranged in multiple battery sections of the battery pack. The method includes connecting a diagnostic service tool (DST) to the battery pack, then measuring a set of battery parameters using one or more electrical sensors, including measuring a corresponding voltage of each of the battery cells or cell groups, and possibly temperature. The method further includes calculating, via the DST using the set of battery parameters, a section-average state of charge (SOC) of each of the battery sections, and identifying, from among the battery cells or cell groups of each respective one of the battery sections, a particular one of the battery cells or cell groups having a lowest cell SOC.

Additionally, the method in this embodiment includes calculating, via the DST for each respective one of the battery sections, a ΔSOC value as a difference between the section-average SOC and the lowest cell SOC, and also comparing the ΔSOC value for each of the battery sections to a calibrated threshold. Thereafter, the method includes executing a repair action with respect to the battery pack, via the DST, responsive to the ΔSOC value for at least one of the battery sections exceeding the calibrated threshold. Such a repair action could include initiating the repair action via the DST, followed by manual or automated repair to achieve the repair action initiated by the DST.

The battery pack may be in communication with a battery management system (BMS), such that connecting the DST to the battery pack includes connecting the DST to the BMS via a communications link.

The battery pack and the BMS may be part of a motor vehicle in which the battery pack is connected to an electric machine action via a power inverter module.

The DST may include or may be in communication with a display device, with the repair action including displaying a required repair action via the display device.

The repair action may include, responsive to the ΔSOC value for two of the battery sections exceeding the calibrated threshold, the act of replacing the battery pack.

Executing the repair action may include, responsive to the ΔSOC value for a single one of the battery sections exceeding the calibrated threshold, the act of replacing or repairing the single one of the battery sections.

Some embodiments of the method include receiving a data signal from the BMS indicative of a build date of the battery pack, and then determining, via the DST using the data signal and a recorded maintenance history and/or a build parameter history of a population of battery packs, whether the build date falls within a period of time during which a predetermined number of faults are recorded in either or both of the histories. The repair action may entail replacing the battery pack as the repair action when the build date is within the period of time.

Executing the repair action may include automatically completing a repair order and a bill of materials via the DST.

A diagnostic service tool is also disclosed for diagnosing faults in the above-noted battery pack. The tool includes a processor and memory on or within which is recorded instructions executable by the processor, with execution of the instructions causing the diagnostic service tool, when connected to the battery pack, to receive a set of battery parameters from one or more electrical sensors, including a corresponding voltage of each of the battery cells or cell groups. The tool also calculates, using the set of battery parameters, a section-average SOC of each of the battery sections and identifies, from among the battery cells or cell groups of each respective one of the battery sections, a particular one of the battery cells or cell groups having a lowest cell SOC.

The tool is also configured to calculate, for each respective one of the battery sections, a ΔSOC value as a difference between the section-average SOC and the lowest cell SOC, compare the ΔSOC value for each of the battery sections to a calibrated threshold, and execute a repair action with respect to the battery pack responsive to the ΔSOC value for at least one of the battery sections exceeding the calibrated threshold.

The above summary is not intended to represent every possible embodiment or every aspect of the present disclosure. Rather, the foregoing summary is intended to exemplify some of the novel aspects and features disclosed herein. The above features and advantages, and other features and advantages of the present disclosure, will be readily apparent from the following detailed description of representative embodiments and modes for carrying out the present disclosure when taken in connection with the accompanying drawings and the appended claims.

### BRIEF DESCRIPTION OF THE DRAWINGS

FIG. 1 is a schematic illustration of an example motor vehicle having an electric powertrain, a multi-cell propulsion battery pack, and a portable service tool in the form of a diagnostic service tool (DST) that is configured to diagnose predetermined faults of the battery pack according to the present method.

FIG. 2 is a schematic illustration of an example cell group configuration usable as part of the battery pack shown in FIG. 1.

FIG. 3 is a plot of a possible state of charge distribution for an example set of battery cell groups.

FIG. 4 is a flow chart describing an example embodiment of a method for diagnosing faults in the battery pack shown in FIG. 1.

The present disclosure is susceptible to modifications and alternative forms, with representative embodiments shown by way of example in the drawings and described in detail below. Inventive aspects of this disclosure are not limited to the particular forms disclosed. Rather, the present disclosure is intended to cover modifications, equivalents, combinations, and alternatives falling within the scope of the disclosure as defined by the appended claims.

### DETAILED DESCRIPTION

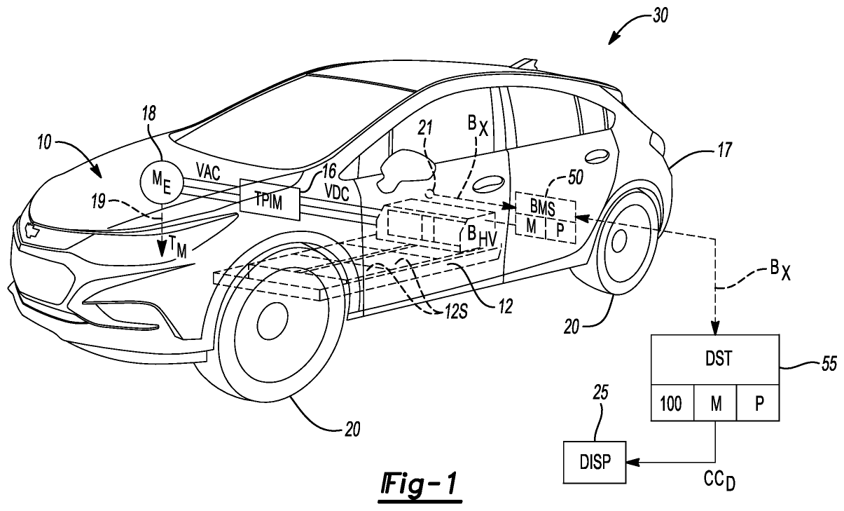

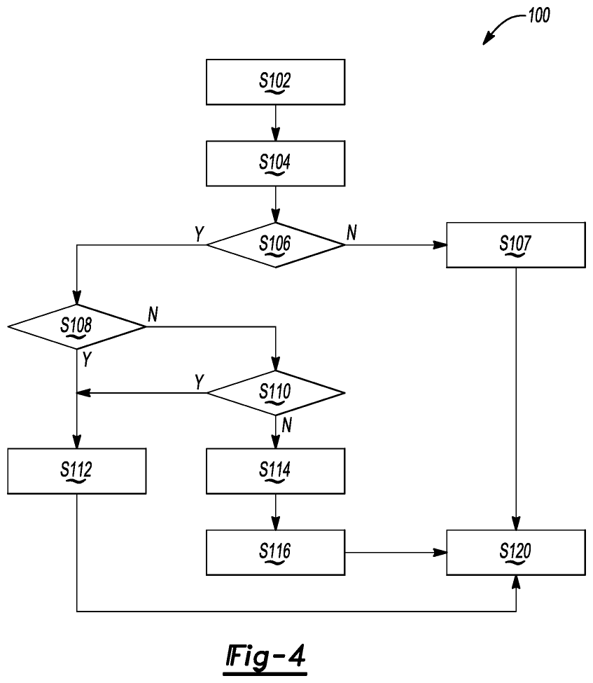

Referring to the drawings, wherein like reference numerals are used to identify like or identical components in the various views, an example powertrain system 10 is depicted in FIG. 1. The powertrain system 10 includes a multi-cell, rechargeable battery pack (B_{HV}) 12, with the subscript “HV” as used herein representing high-voltage. In turn, the term “high-voltage” refers to voltage levels of about 60-300V or more in some embodiments, with voltage levels as low as 18-60V being “high-voltage” relative to 12-15V auxiliary voltage levels depending on the desired use of the powertrain system 10 and the battery pack 12. The powertrain system 10 includes a battery management system (BMS) 50 or other onboard battery controller. As explained below, a diagnostic service tool (DST) 55 configured as a portable service scan tool/computer, e.g., a J2534-compatible service tool, is programmed with a computer-executable algorithm embodying a method 100, an example of which is described below with reference to FIG. 4.

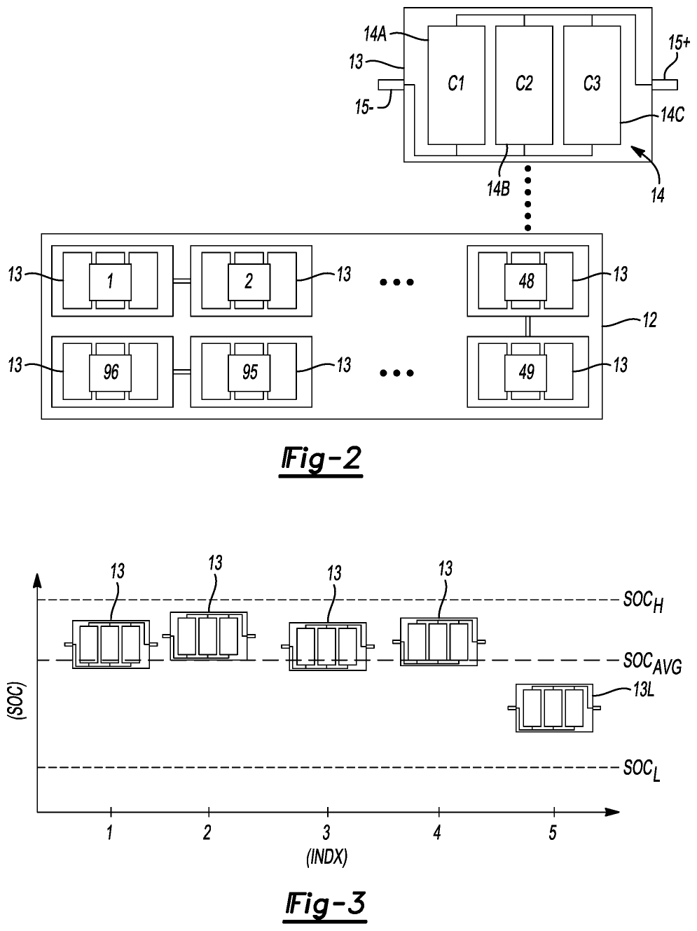

In real-time, the BMS 50 may be used to estimate a remaining amount of usable energy/electrical power in the battery pack 12 or individual battery sections 12S of the battery pack 12, as well as to monitor electrical parameters relevant to the overall control and health of the battery pack 12. For instance, the BMS 50 may monitor voltage, current, state of charge, and temperature of the battery pack 12 and, where possible, its constituent battery sections 12S or battery cells 14 (see FIG. 2). When the BMS 50 is used in an example vehicle 30 as shown in FIG. 1, e.g., a battery electric or hybrid electric motor vehicle, the BMS 50 may estimate a remaining electric range of travel of the vehicle 30 and/or perform other control functions to ensure proper operation of the battery pack 12.

With respect to the exemplary vehicle 30, the powertrain system 10 may be optionally embodied as or for use in a motor vehicle having a set of road wheels 20. At least some of the road wheels 20 are driven wheels, with powered rotation of such road wheels 20 propelling the vehicle 30. Alternatively, the powertrain system 10 of FIG. 1 may be used to power other types of vehicles, such as but not limited to rail vehicles/trains, aircraft, and marine vessels. Likewise, the powertrain system 10 may be used in non-vehicular applications, including powerplants, robots, mobile platforms, hoists, drills, or other such power equipment. For illustrative simplicity and consistency, the vehicle 30 will be presented hereinafter as an example application of the powertrain system 10 without limiting the powertrain system 10 to such an embodiment.

Referring briefly to FIG. 2, the battery pack 12 of FIG. 1 is constructed from serial connections of one or more battery cells 14, which may be a series string of singular battery cells 14 or a connected series of battery cell groups 13. Each battery cell group 13 may include individual battery cells 14, shown for example as a triplet of battery cells 14A, 14B, and 14C. As noted above, the battery cells 14 include a thin layer of insulating material (not shown) disposed between positive (+) and negative (−) metal electrode foils. Although omitted for clarity, the electrode foils are enclosed within a sealed outer pouch containing an electrolyte material, with extensions of the electrode foils protruding from the pouch as positive and negative cell tabs 15+ and 15−, respectively. The cell tabs are ultimately welded together via interconnecting members or weld caps (not shown) to construct the battery pack 12.

In the example cell triplet embodiment of FIG. 2, the three battery cells 14A, 14B, and 14C, also labeled C1, C2, and C3 for clarity, may be connected in electrical parallel within the cell group 13. An application-specific number of the battery cell groups 13 is connected together in electrical series to construct the battery pack and provide a task-suitable voltage capacity. For instance, ninety-six (96) or more of the illustrated cell groups 13 may be used in the illustrated example configuration of the battery pack 12, as represented by cell groups 1, 2, . . . , 48, 49, . . . 95, and 96. More or fewer battery cells 14 or cell groups 13 may be used in other embodiments.

FIG. 3 illustrates five example battery cell groups 13 of a given battery section 12S of FIG. 1 at different states of charge, with the state of charge (SOC) depicted on the vertical axis and the cell index (INDX), i.e., nominal cell groups numbered 1, 2, 3, 4, and 5, depicted on the horizontal axis. The battery pack 12 or each battery section 12S may have upper and lower SOC limits labeled SOCH and SOCL, respectively, above or below which the BMS 50 may shut down operation of the battery pack 12, with the battery section 12S also having a section-average SOC (SOC_{AVG}). The cell group 13 having the lowest cell SOC is labeled 13L.

The section-average SOC may be determined in various ways, for example using the approach disclosed in U.S. Pat. No. 9,575,128 to Frost et al., which is hereby incorporated by reference in its entirety. Other approaches include referencing a lookup table indexed by an average section voltage, i.e., a voltage across a first and last battery cell 14/cell group 13 of a given battery section 12S. The average section voltage may be calculated by dividing a measured, modeled, calculated, or otherwise determined section voltage for a given battery section 12S by the number of battery cells 14/cell groups 13 used in the battery section 12S, i.e.,

$${V}_{AVG} = \frac{{V}_{S}}{\# Cells}$$

where V_{AVG} is the average cell voltage for the battery section 12S, Vs is the section voltage, and # Cells is the number of battery cells 14 or cell groups 13 in the battery section 12S. Such information may be used by the DST 55 of FIG. 1 in executing the method 100.

Referring once again to FIG. 1, in the depicted exemplary powertrain system 10, the battery pack 12 is electrically connected to an electric machine (M_{E}) 18, such as a traction motor or motor-generator unit, via a traction power inverter module (TPIM) 16. The battery pack 12 operates as a direct-current energy storage device, and therefore the battery pack 12 is connected to the TPIM 16 via a DC voltage bus (VDC). An alternating-current voltage bus (VAC) is used to connect the TPIM 16 to the electric machine 18. Motor output torque (arrow T_{M}) is delivered via a rotor 19 of the electric machine 18 to a coupled load. In the example vehicle 30 of FIG. 1, for instance, the coupled load may be the set of drive wheels 20 positioned with respect to a vehicle body 17, with the motor output torque (arrow T_{M}) used alone or in conjunction with an optional internal combustion engine (not shown) to propel the vehicle 30.

Further with respect to the BMS 50, this device is in communication with the battery pack 12 and configured to receive measured battery signals (arrow B_{X}) in real time, i.e., during ongoing operation of the powertrain system 10. The BMS 50 may include a processor (P) and memory (M). Battery signals (arrow B_{X}) include, but are not necessarily limited to, the voltage of the battery pack 12 and each of its constituent battery sections 12S and battery cells 14/cell groups 13, a pack current (total current flowing into the battery pack 12), and a pack and/or cell/cell group-level temperature, which may be respectively measured and reported via a set of sensors 21 positioned with respect to the battery pack 12. The memory (M) includes tangible, non-transitory memory, e.g., read only memory, e.g., optical, magnetic, flash, etc. The BMS 50 also includes sufficient amounts of random-access memory, electrically-erasable programmable read only memory, and the like, as well as a high-speed clock and counter, analog-to-digital and digital-to-analog circuitry, and input/output circuitry and devices, as well as appropriate signal conditioning and buffer circuitry.

Separate from the vehicle 30 and its resident BMS 50, the DST 55 is a portable electronic computer device having a display screen (DISP) 25 that is configured to interface directly with the BMS 50 and/or the battery pack 12 during service of the vehicle 30. The DST 55 is programmed with instructions embodying the present method 100 of FIG. 4. Execution of the method 100 by the DST 55 enables the DST 55 to automatically identify and diagnose predetermined faults of the battery pack 12 within a service facility without requiring offsite analysis in the manner summarized above. Upon execution of the method 100, the DST 55 automatically generates and transmits diagnostic signals (arrow CCD) to initiate repair or replacement actions in the above-noted service context. The diagnostic signals (arrow CCD) may include, in certain embodiments, a set of data signals transmitted to the display device 25, such as a display screen attached to the DST 55 or located in the service facility.

Similar to the BMS 50, the DST 55 of FIG. 1 includes a processor (P) and memory (M), with the memory (M) including tangible, non-transitory memory, e.g., read only memory, e.g., optical, magnetic, flash, etc. Likewise, the DST 55 includes sufficient amounts of random-access memory, electrically-erasable programmable read only memory, etc., as well as a high-speed clock and counter, analog-to-digital and digital-to-analog circuitry, and input/output circuitry and devices, and appropriate signal conditioning and buffer circuitry. The battery signals (arrow B_{X}) are available to the DST 55 when conducting the method 100, e.g., provided directly from the battery pack 12 and/or through an interfaced connection with the BMS 50.

FIG. 4 depicts an exemplary embodiment of the present method 100. Commencing with step S102, the DST 55 determines the cell voltages for each of the battery cells 14 or cell groups 13, and then associates each of the cell voltages with a corresponding one of the battery sections 12S. That is, each battery cell 14/cell group 13 resides within a corresponding battery section 12S within the battery pack 12. When the cell voltages (and possibly other values such as temperature) are measured and reported to the DST 55, e.g., directly or via communication with the BSM 50, the corresponding location of each battery cell 14/cell group 13 providing the reported voltage data is uniquely identified. The method 100 proceeds to step S104 when the DST 55 finishes collecting and organizing the cell voltage data.

Step S104 includes determining an average SOC and a minimum cell SOC for each battery section 12S of the battery pack 12, again using the DST 55. Some example approaches for deriving the section-average SOC are set forth above with reference to FIG. 3, e.g., by adding the individual SOCs of each constituent battery cell 14/cell group 13 and dividing by the total number of battery cells 14/cell groups 13 in the battery section 12S, using a voltage-to-SOC lookup table, etc. For the minimum cell SOC, the DST 55 may compare the individual SOCs for each of the battery cells 14/cell groups 13 to each other and select the lowest value. The method 100 proceeds to step S106 once the DST 55 has derived the section average SOC and the minimum cell SOC for each of the battery sections 12S.

At step S106, for each battery section 12S of the battery pack 12, the DST 55 again compares the data from step S104, i.e., the minimum cell SOC and the section-average SOC, to calculate a difference or delta state of charge (ΔSOC) therebetween, where ΔSOC=SOC_{AVG}−SOC_{MIN} for each of the battery sections 12S. The output of step S106 is a set of ΔSOC values, with one ΔSOC value per battery section 12S. The DST 55 next compares the individual ΔSOC values to a calibrated ΔSOC threshold. Such a threshold may be determined as a percentage difference, for instance a minimum cell SOC at least 5 to 10 percent lower than the corresponding section-average SOC. The method 100 proceeds to step S107 when the calibrated ΔSOC threshold is not reached, and to step S108 in the alternative when the calibrated ΔSOC threshold is reached.

At step S107, the DST 55 of FIG. 1 determines from the results of step S106 that repair of the battery pack 12 is not presently required, and thereafter sets a corresponding diagnostic code in memory (M) of the DST 55 indicative of such a diagnostic result. The method 100 thereafter proceeds to step S120.

Step S108 entails determining, via the DST 55, whether the results of step S106 indicate that more than one battery section 12S has a threshold high ΔSOC value. Such a result could occur when the minimum cell SOC for a given battery section 12S is at least 5 to 10 percent lower than the average SOC for that particular battery section 12S. The method 100 proceeds to step S110 when just one battery section 12S has a threshold high ΔSOC value, and to step S112 in the alternative when multiple battery sections 12S have a threshold high ΔSOC calculated according to step S106.

Step S110 is arrived at when the DST 55 determines, at step S108, that just one battery section 12S has a threshold high ΔSOC value. Step S110 includes determining whether the subject battery pack 12 has a build date or date of manufacture falling in a period of time in which a maintenance history and/or a build parameter history of a population of the battery packs 12 shows that a predetermined number of faults have been recorded in the maintenance history and/or the build parameter history, or that otherwise indicates that a high number of defective battery cells 14/cell groups 13 may have been used during a population corresponding to a given batch or build. That is, given that battery packs 12 are often assembled using battery cells 14/cell groups 13 from the same supplier batch, historical quality information may be used as part of step S110 to identify whether repair of the battery pack 12 may not be a cost-effective option.

To gain this knowledge, the DST 55 may receive a data signal from the BMS 50 indicative of the build date of the battery pack 12, e.g., as part of the battery signals (arrow B_{X}), and then determine, using the data signal and maintenance and/or build parameter history, whether the build date is within the period of time during which a predetermined number of faults are recorded during the respective maintenance and/or build parameter history. Build date information may be part of a date/time stamp or code of the particular battery pack 12 being diagnosed, information that may be available to the DST 55 through its communications interface with the BMS 50 and/or the battery pack 12, or through a corresponding communications port of the vehicle 30 in such an embodiment. The DST 55 may record in its memory (M) that the battery pack 12 was or was not built during the above-noted period of suspect quality, or with components from a suspect batch that may be predictive of long-term health of the battery pack 12. The method 100 proceeds to step S112 when the subject battery pack 12 was built during such a period, and to step S114 in the alternative when the battery pack 12 was not produced with what historical maintenance records may indicate as being potentially suspect battery cells 14/cell groups 13.

Step S112 of the method 100 is reached when the DST 55 determines at step S108 that multiple different battery sections 12S have a threshold high ΔSOC value, or when the battery pack 12 having at least one battery section 12S with a threshold high ΔSOC value was built during the above-noted window of time in which the quality or life of the battery cells 14 may be suspect. Step S112 includes recording a corresponding diagnostic code indicative of a first required repair action. For instance, the diagnostic code may call for the replacement of the entire battery pack 12.

In general, the battery cells 14/cell groups 13 used in a battery pack 12 tend to be built around the same time, as noted above. If a battery pack 12 has multiple defective battery cells 14, the DST 55 may determine that there is an increased probability of a particular failure mode repeating itself when two battery sections 12S are deemed defective in the battery pack 12. Therefore, the method 100 may be used to avoid repeat visits to the service department for the same battery pack 12 by deciding not to replace two battery sections 12S, but instead replacing the battery pack 12 as a whole. The method 100 proceeds to step S120 upon completion of step S112.

At step S114, the DST 55 of FIG. 1 identifies the battery section 12S having the defective battery cell 14/cell group 13 and proceeds to step S116. That is, the DST 55 is aware, from its execution of the foregoing steps, that there is a single battery section 12S with a threshold high ΔSOC value, and that the particular battery section 12S is not part of a battery pack 12 built with suspect battery cells 14/cell groups 13. Thus, the DST 55 temporarily records the identity of the defective battery cell 14/cell group 13 in its memory (M) and proceeds to step S116.

At step S116, the DST 55 records a diagnostic code indicative of a second required repair action. The diagnostic code may call for replacement of the faulty battery section 12S as the second required repair action. The method 100 thereafter proceeds to step S120.

Step S120 includes executing a diagnostic control and/or repair action in response to the recorded diagnostic code. Step S120 may include displaying the first or second required repair actions from steps S112 or S116, respectively, via the display device 25 of FIG. 1. As part of step S120, a repair order and bill of materials may be automatically transmitted to the repair facility operating the DST 55, such that the displayed repair action is automatically queued and initiated at the repair facility.

Depending on the severity of the diagnosed faults, e.g., the magnitude of the determined ΔSOC value or the amount by which the ΔSOC value exceeds a calibrated threshold, whether due to a low cell or a defective cell sensing operation, the DST 55 may transmit control signals to the BSM 50 that cause the BMS 50 to limit operation of the battery pack 12 in some manner, e.g., by setting lower voltage and/or current limits of the battery pack 12. Such an action may help protect the battery pack 12 from damage in a weakened state, and would reduce the permissible level of output torque from the electric machine 18 of FIG. 1 in the example vehicle 30. Such a control action would in turn allow for limited operation of the vehicle 30 until repair could be scheduled.

Alternatively, or concurrently, the step S120 may notify the user of the system employing the faulty battery pack 12, e.g., the operator of the vehicle 30 of FIG. 1, as to the diagnostic result so that the user may schedule or approve the recommended repair action. Step S120 may likewise include displaying a “no fault found” message indicative of a no-fault diagnostic code from step S107 when a threshold high ΔSOC value is not detected in the battery pack 12 at step S106.

The above-described method 100 and DST 55 as disclosed above are therefore intended to increase the efficiency of dealership service departments with respect to diagnosing low-cell voltage or cell-sensing issues. This is accomplished by integrating logic in the DST 55 that enables a service technician to receive a disposition and repair strategy directly from use of the DST 55. As part of this disposition, the service technician may be able to identify particular battery cells 14/cell groups 13, battery sections 12S, battery packs 12, and/or sensing equipment requiring repair or replacement.

Moreover, the use of ΔSOC information in lieu of voltage or voltage differential information may help reduce errors leading to the repair or replacement of what are in fact a battery pack 12 with properly functioning battery cells 14/cell groups 13 or battery sections 12S. Such errors may be more prevalent in battery packs 12 having battery chemistries demonstrating non-linear SOC-open-circuit voltage (OCV) curves, e.g., lithium-ion batteries.

While the DST 55 may be used in the maintenance scenario as described above, one of ordinary skill in the art will appreciate that the present teachings could it be used onboard the vehicle 30, proactively, with the diagnostic results and control actions of the powertrain system 10 reported to a dealership, repair facility, or other remote location, e.g., via a telematics unit. Thus, the method 100 or designated processes thereof may be performed onboard or offboard as needed to realize the various benefits set forth herein.

Likewise, the integration and use of the DST 55 with the display device 25 of FIG. 1 provides real-time visual feedback of the fault location to the service technician, thereby avoiding the need for remote communication with a distant battery repair facility in the overall process of diagnosing and repairing the above-described battery pack 12. These and other attendant benefits will be readily appreciated by those of ordinary skill in the art in view of this disclosure.

While some of the best modes and other embodiments have been described in detail, various alternative designs and embodiments exist for practicing the present teachings defined in the appended claims. Those skilled in the art will recognize that modifications may be made to the disclosed embodiments without departing from the scope of the present disclosure. Moreover, the present concepts expressly include combinations and sub-combinations of the described elements and features. The detailed description and the drawings are supportive and descriptive of the present teachings, with the scope of the present teachings defined solely by the claims.

What is claimed is:

1. A method for diagnosing faults in a battery pack having a plurality of series-connected battery cells or cell groups, wherein the battery cells or cell groups are arranged in multiple battery sections of the battery pack, the method comprising:
connecting a diagnostic service tool (DST) to the battery pack;
measuring a set of battery parameters using one or more electrical sensors, including measuring a corresponding voltage of each of the battery cells or cell groups;
calculating, via the DST using the set of battery parameters, a section-average state of charge (SOC) of each of the battery sections;
identifying, from among the battery cells or cell groups of each respective one of the battery sections, a particular one of the battery cells or cell groups having a lowest cell SOC;
calculating, via the DST for each respective one of the battery sections, a ΔSOC value as a difference between the section-average SOC and the lowest cell SOC;
comparing the ΔSOC value for each of the battery sections to a calibrated threshold; and
executing a repair action with respect to the battery pack, via the DST, responsive to the ΔSOC value for at least one of the battery sections exceeding the calibrated threshold.

2. The method of claim 1, wherein the battery pack is in communication with a battery management system (BMS), and wherein connecting the DST to the battery pack includes connecting the DST to the BMS via a communications link.

3. The method of claim 2, wherein the battery pack and the BMS are part of a motor vehicle in which the battery pack is connected to an electric machine action via a power inverter module.

4. The method of claim 1, wherein the DST includes or is in communication with a display device, and wherein the repair action includes displaying a required repair action via the display device.

5. The method of claim 1, wherein executing a repair action includes, responsive to the ΔSOC value for two of the battery sections exceeding the calibrated threshold, replacing the battery pack.

6. The method of claim 1, wherein executing a repair action includes, responsive to the ΔSOC value for a single one of the battery sections exceeding the calibrated threshold, replacing or repairing the single one of the battery sections.

7. The method of claim 1, further comprising:
receiving a data signal from the BMS indicative of a build date of the battery pack;
determining, via the DST using the data signal and a maintenance history and/or a build parameter history of a population of battery packs, whether the build date is within a period of time during which a predetermined number of faults are recorded in the maintenance history and/or the build parameter history; and
replacing the battery pack as the repair action when the build date is within the period of time.

8. The method of claim 1, wherein executing a repair action includes automatically completing a repair order and bill of materials via the DST.

9. A diagnostic service tool for diagnosing faults in a battery pack having a plurality of series-connected battery cells or cell groups, wherein the battery cells or cell groups are arranged in multiple battery sections of the battery pack, wherein the tool includes a processor and memory on or within which is recorded instructions executable by the processor, and wherein execution of the instructions by the processor causes the diagnostic service tool, when connected to the battery pack, to:
receive a set of battery parameters from one or more electrical sensors, including a corresponding voltage of each of the battery cells or cell groups;
calculate, using the set of battery parameters, a section-average state of charge (SOC) of each of the battery sections;
identify, from among the battery cells or cell groups of each respective one of the battery sections, a particular one of the battery cells or cell groups having a lowest cell SOC;
calculate, via the DST for each respective one of the battery sections, a ΔSOC value as a difference between the section-average SOC and the lowest cell SOC;
compare the ΔSOC value for each of the battery sections to a calibrated threshold; and
execute a repair action with respect to the battery pack responsive to the ΔSOC value for at least one of the battery sections exceeding the calibrated threshold.

10. The diagnostic service tool of claim 9, wherein the battery pack is connected to a battery management system (BMS), and wherein the diagnostic service tool is configured to connect to the BMS via a communications link.

11. The diagnostic service tool of claim 10, wherein the battery pack and the BMS are part of a motor vehicle in which the battery pack is connected to an electric machine action via a power inverter module, and wherein the diagnostic service tool is connected to the BMS via a communications port of the motor vehicle.

12. The diagnostic service tool of claim 9, wherein the diagnostic service tool includes or is in communication with a display device, and is configured to display the required repair action via the display device.

13. The diagnostic service tool of claim 9, wherein the repair action includes initiating replacement of the battery pack responsive to the ΔSOC value for two of the battery sections exceeding the calibrated threshold.

14. The diagnostic service tool of claim 10, wherein the repair action includes, responsive to the ΔSOC value for a single one of the battery sections, the battery cells, or the cell groups exceeding the calibrated threshold, initiating replacement or repair of the single one of the battery sections, the battery cells, or the cell groups.

15. The diagnostic service tool of claim 10, wherein the diagnostic service tool is configured to:
receive a data signal from the BMS indicative of a build date of the battery pack;
determine, using the data signal and a maintenance history and/or a build parameter history of a population of battery packs, whether the build date is within a period of time during which a predetermined number of faults are recorded in the maintenance history and/or the build parameter history; and
initiate replacement of the battery pack as the repair action when the build date is within the period of time.

16. The diagnostic service tool of claim 10, wherein the repair action includes automatically completing a repair order and bill of materials.
